(19) United States
(12) Patent Application Publication
(10) Pub. No.: US 2024/0203813 A1
(43) Pub. Date: Jun. 20, 2024

(54) SEMICONDUCTOR PACKAGE

(71) Applicant: SAMSUNG ELECTRONICS CO., LTD., Suwon-si (KR)

(72) Inventors: Wooseup HWANG, Suwon-si (KR); Jihye SHIM, Suwon-si (KR)

(21) Appl. No.: 18/364,434

(22) Filed: Aug. 2, 2023

(30) Foreign Application Priority Data
Dec. 20, 2022 (KR) 10-2022-0179038

(51) Int. Cl. H01L 23/31; H01L 23/00; H01L 23/48; H01L 25/065

(52) U.S. Cl. CPC H01L 23/3171; H01L 23/481; H01L 24/30; H01L 24/32; H01L 25/0657; H01L 24/14; H01L 24/16; H01L 24/73; H01L 2224/14181; H01L 2224/16145; H01L 2224/30181; H01L 2224/32145; H01L 2224/73204

(57) ABSTRACT

A semiconductor package includes a first semiconductor die, second semiconductor dies each of which has a width less than a width of the first semiconductor die and which are stacked on the first semiconductor die, a first non-conductive layer between the first semiconductor die and a lowermost second semiconductor die, and a second non-conductive layer between adjacent ones of the second semiconductor dies. Each of the second semiconductor dies includes a first substrate that has a first front surface and a first rear surface, a first interlayer dielectric layer that covers the first front surface, first through electrodes that penetrate the first substrate, and a first passivation layer that covers the first rear surface. A first groove is in the first passivation layer and a portion of the first substrate. The second non-conductive layer is within the first groove.

### CROSS-REFERENCE TO RELATED APPLICATION

This U.S. nonprovisional application claims priority under 35 U.S.C. § 119 to Korean Patent Application No. 10-2022-0179038 filed on Dec. 20, 2022 in the Korean Intellectual Property Office, the disclosure of which is hereby incorporated by reference in its entirety.

### BACKGROUND

The present inventive concepts relate to semiconductor packages.

A semiconductor package is provided to implement an integrated circuit chip to qualify for use in electronic products. A semiconductor package is typically configured such that a semiconductor die is mounted on a printed circuit board (PCB) and bonding wires or bumps are used to electrically connect the semiconductor die to the printed circuit board. With the development of the electronic industry, many studies have been conducted to improve reliability and durability of semiconductor packages.

### SUMMARY

Some embodiments of the present inventive concepts provide semiconductor packages with increased reliability.

The objects of the present inventive concepts are not limited to those described herein, and other objects which have not been mentioned will be clearly understood to those skilled in the art from the following description.

According to some embodiments of the present inventive concepts, a semiconductor package may comprise: a first semiconductor die; a plurality of second semiconductor dies stacked on the first semiconductor die, each of the second semiconductor dies having a width less than a width of the first semiconductor die; a first non-conductive layer between the first semiconductor die and a lowermost one of the second semiconductor dies; and a second non-conductive layer between adjacent ones of the second semiconductor dies. Each of the second semiconductor dies may include: a first substrate that has a first front surface and a first rear surface; a first interlayer dielectric layer that covers the first front surface; a plurality of first through electrodes that penetrate the first substrate; and a first passivation layer that covers the first rear surface. A first groove may be in the first passivation layer and a portion of the first substrate. The second non-conductive layer is within and may fill the first groove.

According to some embodiments of the present inventive concepts, a semiconductor package may comprise: a first semiconductor die; a plurality of second semiconductor dies stacked on the first semiconductor die, each of the second semiconductor dies having a width less than a width of the first semiconductor die; a first non-conductive layer between the first semiconductor die and a lowermost one of the second semiconductor dies; and a second non-conductive layer between adjacent ones of the second semiconductor dies. Each of the second semiconductor dies may include: a first substrate that has a first front surface and a first rear surface; a first interlayer dielectric layer that covers the first front surface; a plurality of first through electrodes that penetrate the first substrate; and a first passivation layer that covers the first rear surface. A first groove may be in a portion of the first interlayer dielectric layer. The second non-conductive layer is within and may fill the first groove.

According to some embodiments of the present inventive concepts, a semiconductor package may comprise: a first semiconductor die; a plurality of second semiconductor dies stacked on the first semiconductor die, each of the second semiconductor dies having a width less than a width of the first semiconductor die; a first non-conductive layer between the first semiconductor die and a lowermost one of the second semiconductor dies; and a second non-conductive layer between adjacent ones of the second semiconductor dies. The first semiconductor die may include: a first substrate that has a first front surface and a first rear surface; a first interlayer dielectric layer that covers the first front surface; a plurality of first through electrodes that penetrate the first substrate; and a first passivation layer that covers the first rear surface. A first groove may be in the first passivation layer and a portion of the first substrate. The first non-conductive layer is within and may fill the first groove. Each of the second semiconductor dies may include: a second substrate that has a second front surface and a second rear surface; a second interlayer dielectric layer that covers the second front surface; a plurality of second through electrodes that penetrate the second substrate; and a second passivation layer that covers the second rear surface. A second groove may be in a portion of the second interlayer dielectric layer. A third groove may be in the second passivation layer and the second substrate. The second non-conductive layer is within and may fill the second groove and the third groove. The second groove may have a first width of about 1 μm to about 10 μm.

### BRIEF DESCRIPTION OF THE DRAWINGS

FIG. 1 illustrates a plan view showing a semiconductor package according to some embodiments of the present inventive concepts.

FIG. 2 illustrates a cross-sectional view taken along line A-A′ of FIG. 1.

FIGS. 3A to 3G illustrate enlarged views showing section P1 of FIG. 2.

FIGS. 4A to 4I illustrate cross-sectional views showing a method of fabricating a semiconductor package having the cross-section of FIG. 1.

FIG. 5 illustrates a plan view showing a semiconductor package according to some embodiments of the present inventive concepts.

FIGS. 6A and 6B illustrate enlarged cross-sectional views taken along line B-B′ of FIG. 5.

FIG. 7 illustrates a cross-sectional view showing a semiconductor package according to some embodiments of the present inventive concepts.

FIGS. 8A to 8C illustrate enlarged view showing section P2 of FIG. 7.

FIGS. 9A to 9F illustrate cross-sectional views showing a method of fabricating the semiconductor package of FIG. 7.

FIG. 10 illustrates a cross-sectional view showing a semiconductor package according to some embodiments of the present inventive concepts.

FIG. 11 illustrates an enlarged view showing section P3 of FIG. 10.

FIG. 12 illustrates a cross-sectional view showing a semiconductor package according to some embodiments of the present inventive concepts.

FIG. 13 illustrates an enlarged view showing section P3 of FIG. 10.

### DETAIL PARTED DESCRIPTION OF EMBODIMENTS

Some embodiments of the present inventive concepts will now be described in detail with reference to the accompanying drawings to aid in clearly explaining the present inventive concepts. In this description, the term “semiconductor die” may be called “semiconductor chip.” Such terms as “first” and “second” may be used to simply distinguish identical or similar components from each other, and the sequence of such terms may be changed in accordance with the order of mention. The language “solder ball” may be called “connection member.”

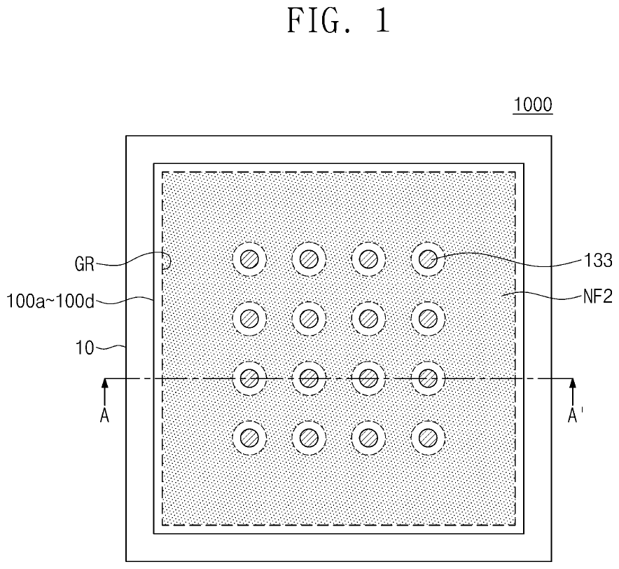

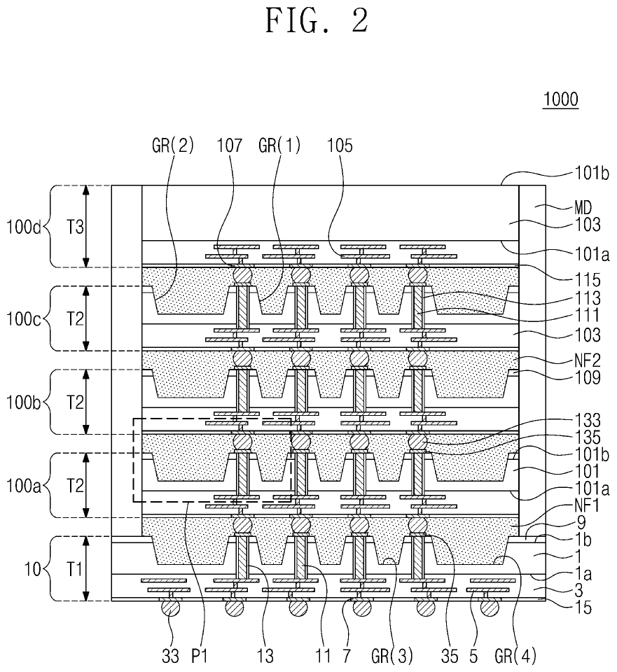

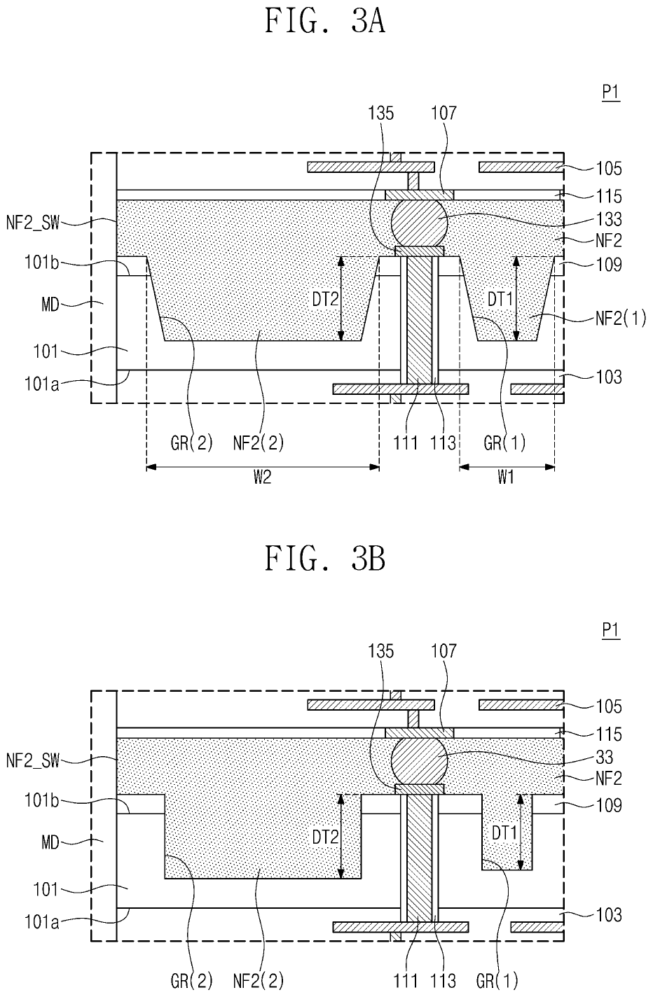

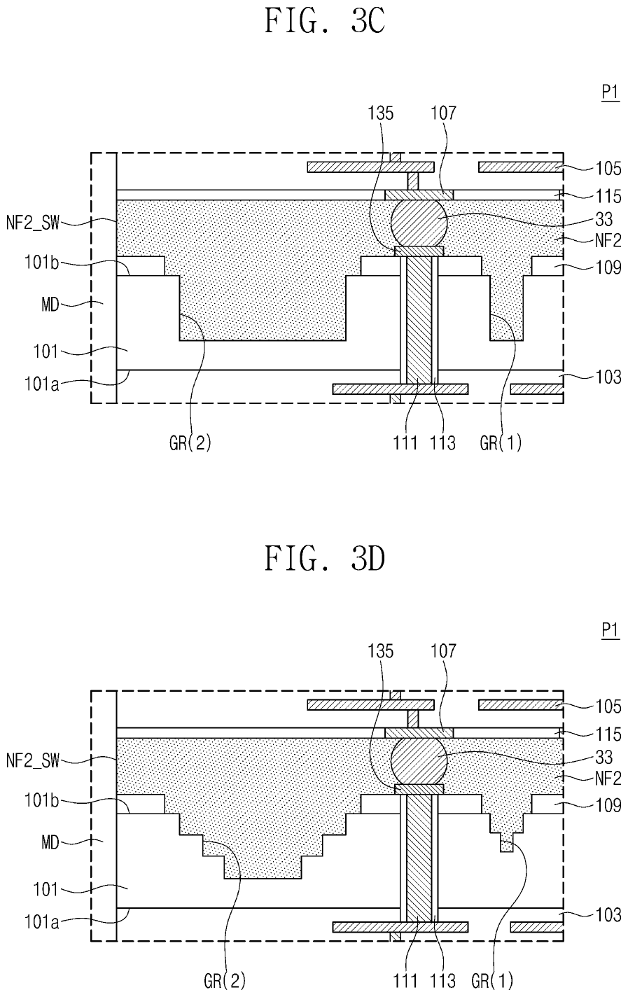

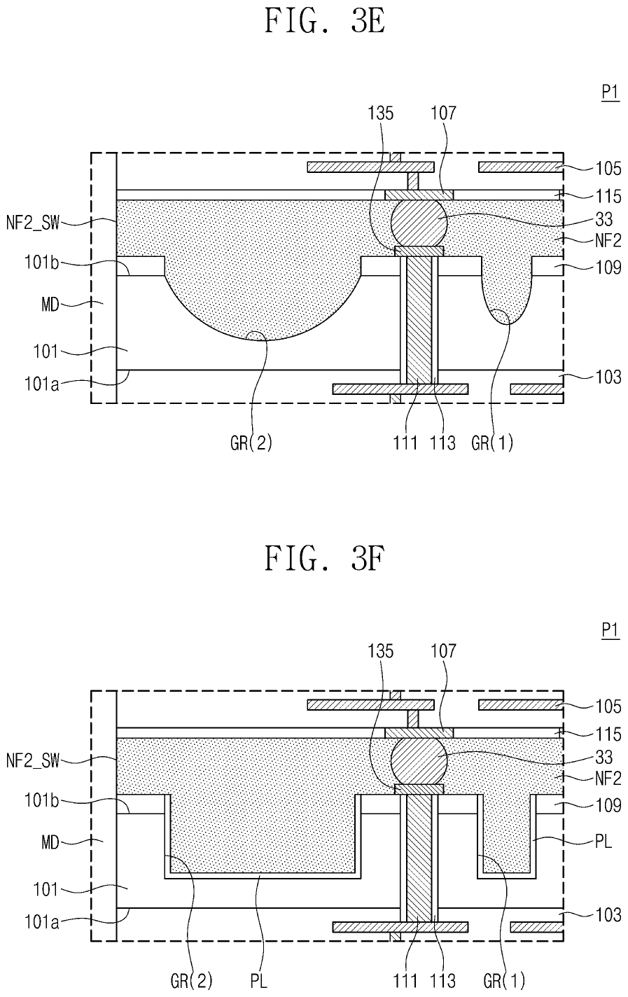

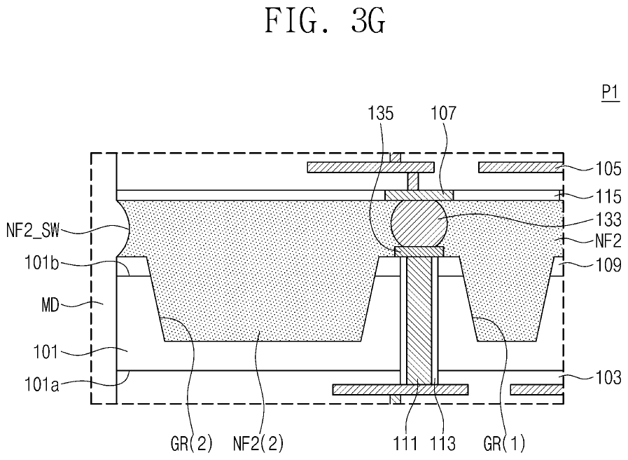

FIG. 1 illustrates a plan view showing a semiconductor package according to some embodiments of the present inventive concepts. FIG. 2 illustrates a cross-sectional view taken along line A-A′ of FIG. 1. FIGS. 3A to 3G illustrate enlarged views showing section P1 of FIG. 2.

Referring to FIGS. 1 and 2, a semiconductor package 1000 according to some embodiments may include second, third, fourth, and fifth semiconductor dies 100a, 100b, 100c, and 100d that are sequentially stacked on a first semiconductor die 10. The first semiconductor die 10 may be of a different type from the second, third, fourth, and fifth semiconductor dies 100a, 100b, 100c, and 100d. The first semiconductor die 10 may be, for example, a logic circuit chip or an interposer substrate. The second, third, fourth, and fifth semiconductor dies 100a, 100b, 100c, and 100d may be the same memory chip. The memory chip may be, for example, dynamic random access memory (DRAM), NAND Flash memory, static random access memory (SRAM), magnetic random access memory (MRAM), phase change random access memory (PRAM), or resistive random access memory (RRAM). The present embodiment discloses a structure where one logic circuit chip and four memory chips are stacked, but the number of the logic circuit chip and the number of the memory chips may be variously changed without being limited thereto. A width of the first semiconductor die 10 may be greater than those of the second, third, fourth, and fifth semiconductor dies 100a, 100b, 100c, and 100d. The semiconductor package 1000 may be, for example, a high bandwidth memory (HBM) chip.

A mold layer MD may cover a top surface of the first semiconductor die 10 and lateral surfaces of the second, third, fourth, and fifth semiconductor dies 100a, 100b, 100c, and 100d. The mold layer MD may include a dielectric resin, for example, an epoxy molding compound (EMC). The mold layer MD may further include fillers, and the fillers may be dispersed in the dielectric resin. The fillers may include, for example, silicon oxide (SiO2). A top surface of the mold layer MD may be coplanar with a second rear surface 101b of the fifth semiconductor die 100d.

The first semiconductor die 10 may include a first substrate 1. The first substrate 1 may have a first front surface 1a and a first rear surface 1b that are opposite to each other. A first interlayer dielectric layer 3 may be disposed on the first front surface 1a. The first interlayer dielectric layer 3 may have therein first transistors (not shown) and multi-layered first wiring lines 5.

First front conductive pads 7 may be disposed on the first interlayer dielectric layer 3. A first solder ball 33 may be bonded to the first front conductive pad 7. The first interlayer dielectric layer 3 may be covered with a first front passivation layer 15. The first rear surface 1b may be covered with a first rear passivation layer 9 First rear conductive pads 35 may be disposed on the first rear passivation layer 9 First through vias 11 may penetrate the first rear passivation layer 9, the first substrate 1, and a portion of the first interlayer dielectric layer 3. Each of the first through vias 11 may connect one of the first wiring lines 5 to one of the first rear conductive pads 35. A first through dielectric layer 13 may be interposed between the first through via 11 and the first substrate 1. The first semiconductor die 10 may have a first thickness T1.

Each of the second, third, fourth, and fifth semiconductor dies 100a, 100b, 100c, and 100d may include a second substrate 101. The second substrate 101 may have a second front surface 101a and a second rear surface 101b that are opposite to each other. A second interlayer dielectric layer 103 may be disposed on the second front surface 101a. The second interlayer dielectric layer 103 may have therein second transistors (not shown) and multi-layered second wiring lines 105.

Second front conductive pads 107 may be disposed on the second interlayer dielectric layer 103. A second solder ball 133 may be bonded to the second front conductive pad 107. The second interlayer dielectric layer 103 may be covered with a second front passivation layer 115. The second rear surface 101b may be covered with a second rear passivation layer 109. Second rear conductive pads 135 may be disposed on the second rear passivation layer 109. In each of the second, third, and fourth semiconductor dies 100a, 100b, and 100c, second through vias 111 may penetrate the second rear passivation layer 109, the second substrate 101, and a portion of the second interlayer dielectric layer 103. Each of the second through vias 111 may connect one of the second wiring lines 105 to one of the second rear conductive pads 135. A second through dielectric layer 113 may be interposed between the second through via 111 and the second substrate 101. Each of the second, third, and fourth semiconductor dies 100a, 100b, and 100c may have a second thickness T2. The second thickness T2 may be the same as or different from the first thickness T1.

The fifth semiconductor die 100d may exclude the second through via 111 and the second through dielectric layer 113. The fifth semiconductor die 100d may not include the second rear passivation layer 109. The fifth semiconductor die 100d may have a third thickness T3. The third thickness T3 may be greater than the second thickness T2.

The first, second, third, fourth, and fifth semiconductor dies 10, 100a, 100b, 100c, and 100d may be spaced apart from each other. The first, second, third, fourth, and fifth semiconductor dies 10, 100a, 100b, 100c, and 100d may be electrically connected to each other through the second solder balls 133 interposed therebetween.

The first, second, third, and fourth semiconductor dies 10, 100a, 100b, and 100c may have their uneven structures on top surfaces thereof. The first, second, third, and fourth semiconductor dies 10, 100a, 100b, and 100c may have their grooves GR. In the plan view of FIG. 1, an area that the grooves GR occupy may correspond to about 10% to about 90% of a planar area except areas of the second rear conductive pads 135 in the second semiconductor die 100a.

Each of the second, third, and fourth semiconductor dies 100a, 100b, and 100c may have first and second grooves GR(1) and GR(2). The first and second grooves GR(1) and GR(2) may be provided in the second rear passivation layer 109 and the second substrate 101. The first grooves GR(1) may be provided between the second through vias 111. The second grooves GR(2) may be disposed adjacent to an end of the second substrate 101 and spaced apart from the first grooves GR(1). When viewed in plan as shown in FIG. 1, the first grooves GR(1) and the second grooves GR(2) may be connected to each other.

As shown in FIG. 3A, each of the first grooves GR(1) may have a first width W1 and a first depth DT1. Each of the second grooves GR(2) may have a second width W2 and a second depth DT2. The second width W2 may be the same as or different from the first width W1. For example, as shown in FIG. 3A or 3B, the second width W2 may be greater than the first width W1. The first depth DT1 may be the same as or different from the second depth DT2. As shown in FIG. 3B, the second depth DT2 may be greater than the first depth DT1. The first width W1 may range, for example, from about 1 μm to about 10 μm. The first depth DT1 may correspond to about 10% to about 80% of the second thickness T2 of FIG. 2.

As shown in FIG. 3A or 3B, on inner sidewalls of the first grooves GR(1) and the second grooves GR(2), a sidewall of the second rear passivation layer 109 and a sidewall of the second substrate 101 may be aligned with each other. Alternatively, as shown in FIG. 3C or 3D, on inner sidewalls of the first grooves GR(1) and the second grooves GR(2), a sidewall of the second rear passivation layer 109 and a sidewall of the second substrate 101 may be offset from each other.

Each of the first and second grooves GR(1) and GR(2) may have a trapezoidal shape in cross section as shown in FIG. 3A, a rectangular shape in cross section as shown in FIG. 3B, a stepwise or staircase shape in cross section as shown in FIG. 3D, or a round or curved shape in cross section as shown in FIG. 3E. The first and second grooves GR(1) and GR(2) may have their inner sidewalls and bottom surfaces that are covered with a protection layer PL, as shown in FIG. 3F.

A first non-conductive layer NF1 may be interposed between the first and second semiconductor dies 10 and 100a. Second non-conductive layers NF2 may be correspondingly interposed between the second to fifth semiconductor dies 100a to 100d. The second non-conductive layers NF2 may fill the first grooves GR(1) and the second grooves GR(2). The second non-conductive layers NF2 may have their sidewalls NF2_SW that are flat as shown in FIG. 3A or inwardly recessed toward a space between the second to fifth semiconductor dies 100a to 100d as shown in FIG. 3G.

Referring to FIG. 3A, the second non-conductive layers NF2 may include first dielectric parts NF2(1) and second dielectric parts NF2(2) that are inserted into the second to fourth semiconductor dies 100a to 100c. The first dielectric parts NF2(1) may be interposed between the second through vias 111. The first dielectric parts NF2(1) may have a first width W1 and a first height DT1. The second dielectric parts NF2(2) may be adjacent to ends of the second to fourth semiconductor dies 100a to 100c and may have a second width W2 and a second height DT2. The second width W2 may be the same as or greater than the first width W1. The second height DT2 may be the same as or greater than the first height DT1.

The first semiconductor die 10 may have third and fourth grooves GR(3) and GR(4). The third grooves GR(3) have an identical or similar shape to that of the first grooves GR(1). The fourth grooves GR(4) have an identical or similar shape to that of the second grooves GR(2). The first non-conductive layer NF1 may be interposed between the first and second semiconductor dies 10 and 100a. The first non-conductive layer NF1 may fill the third and fourth grooves GR(3) and GR(4). The first non-conductive layer NF1 may have an identical or similar shape to that of the second non-conductive layer NF2. The mold layer MD may cover a sidewall of the first non-conductive layer NF1 and a sidewall of the second non-conductive layer NF2.

The first and second substrates 1 and 101 may independently be a semiconductor substrate, a monocrystalline silicon substrate, or a silicon-on-insulator (SOI) substrate. The first and second substrates 1 and 101 may each be called “semiconductor substrate” or “die substrate.” The first and second interlayer dielectric layers 3 and 103 may include a single or multiple layer including at least one selected from a silicon oxide layer, a silicon nitride layer, a silicon oxynitride layer, and a porous dielectric layer. The first and second front passivation layers 15 and 115 and the first and second rear passivation layers 9 and 109 may have a single-layered or multi-layered structure of at least one selected from, for example, silicon nitride, SiCN, and silicon oxide. The protection layer PL may be formed to have a single-layered or multi-layered structure of at least one selected from, for example, silicon oxide and silicon nitride. The first and second through dielectric layers 13 and 113 may be formed of, for example, a silicon oxide layer. The first and second front passivation layers 15 and 115 and the first and second rear passivation layers 9 and 109 may each include metal such as copper, aluminum, cobalt, nickel, or gold. The first and second solder balls 33 and 133 may include, for example, Sn or SnAg. The first and second through vias 11 and 111 may include, for example, copper.

In the semiconductor package 1000 according to the present embodiment, the first, second, third, and fourth semiconductor dies 10, 100a, 100b, and 100c may have their uneven structures caused by the grooves GR formed on the top surfaces thereof. The first and second non-conductive layers NF1 and NF2 may fill the grooves GR. The first and second non-conductive layers NF1 and NF2 may be introduced into the grooves GR when the second to fifth semiconductor dies 100a to 100d are mounted, and thus portions of the first and second non-conductive layers NF1 and NF2 may not protrude laterally from the second to fifth semiconductor dies 100a to 100d and further from a lateral surface of the mold layer MD. Therefore, as the mold layer MD completely encapsulates the second to fifth semiconductor dies 100a to 100d, the semiconductor package 1000 may be free of problem such as delamination and may increase in reliability by preventing introduction of moisture.

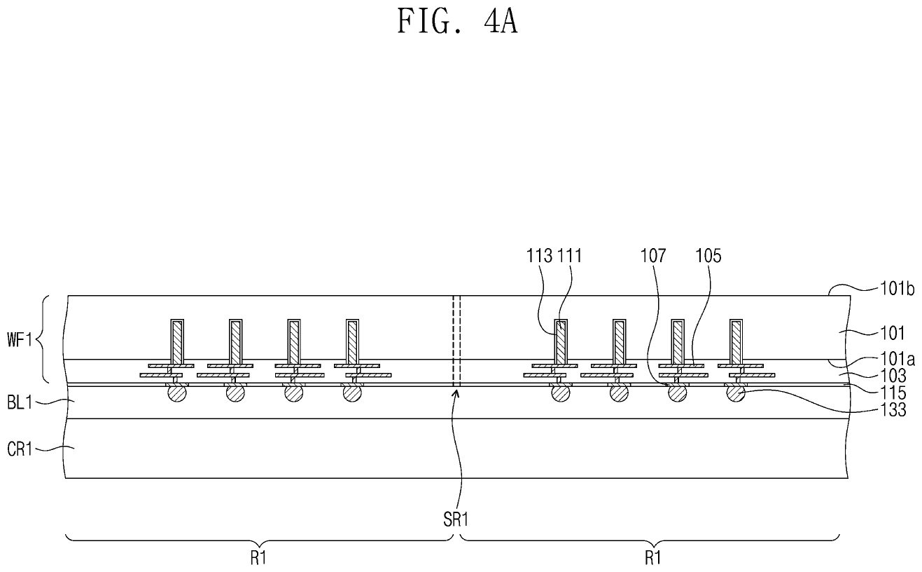

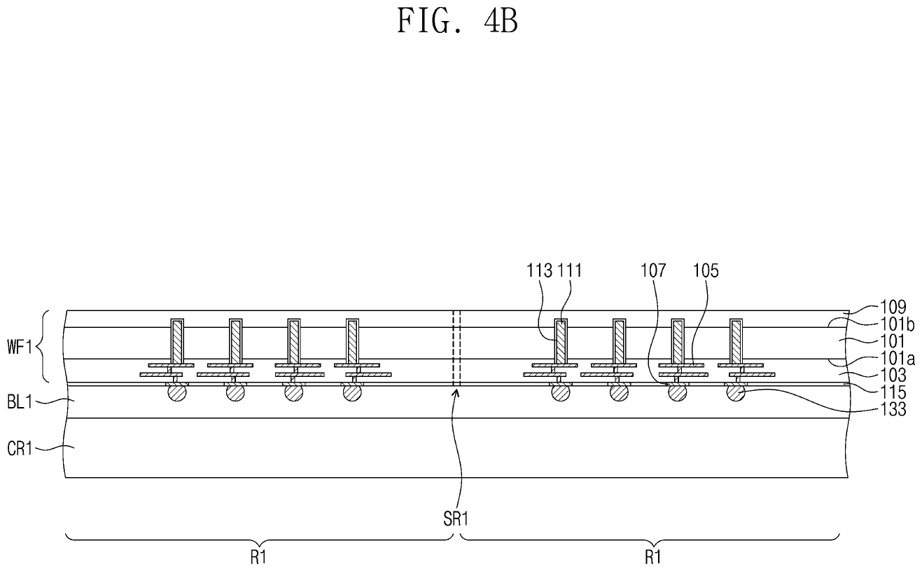

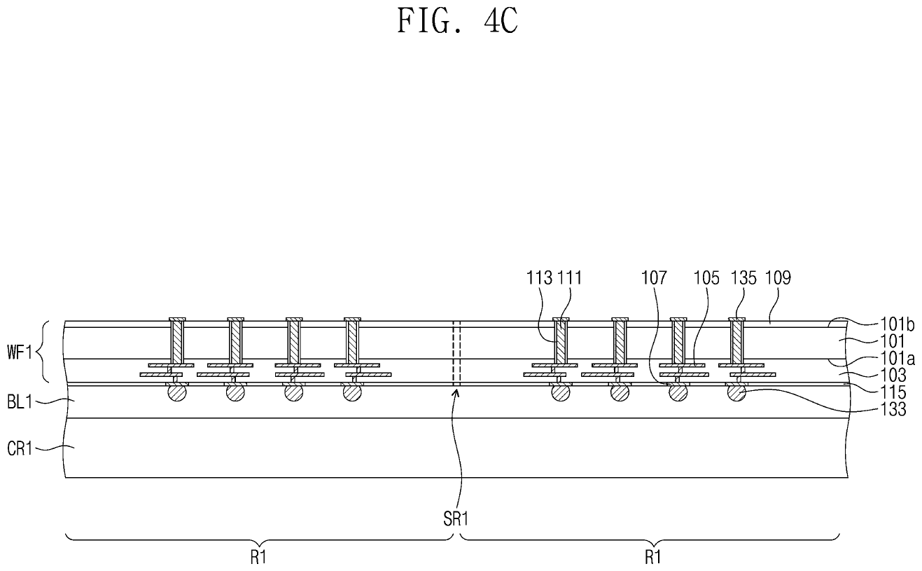

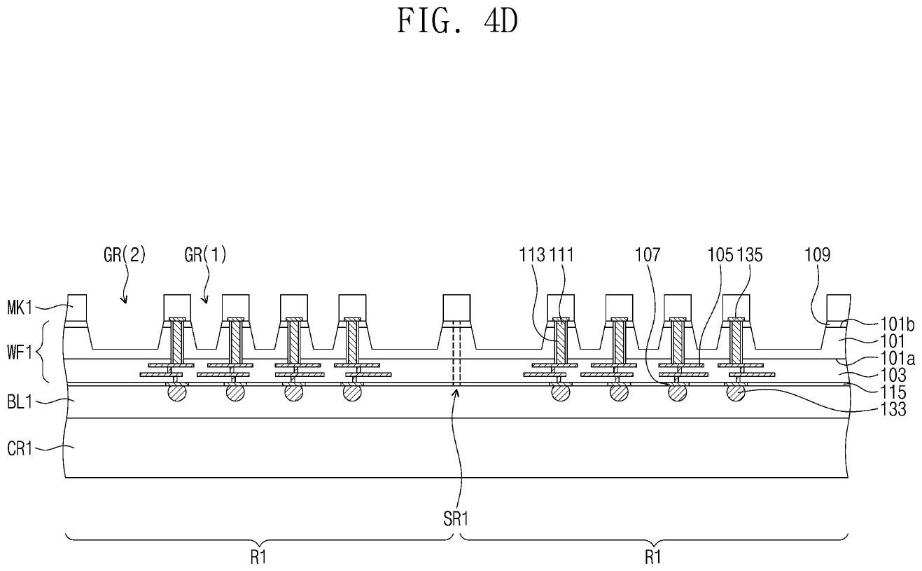

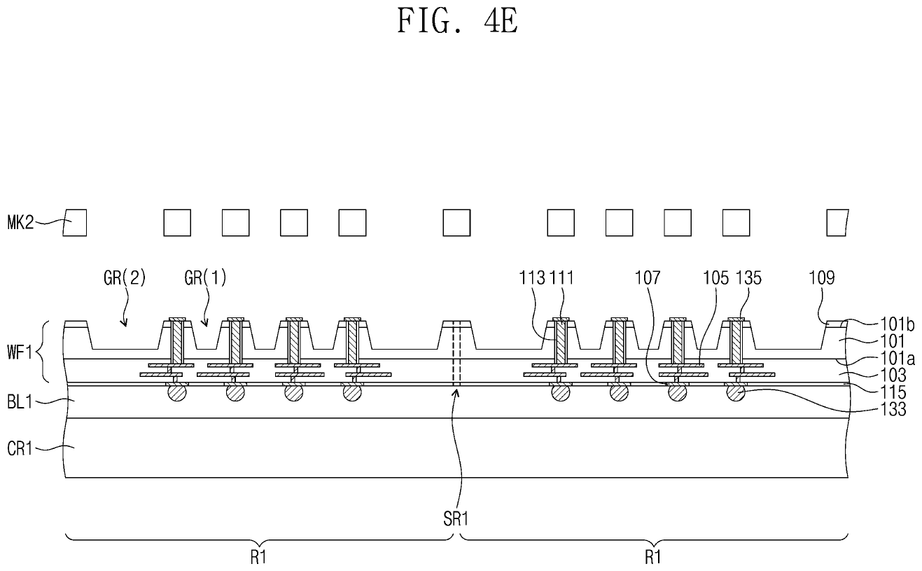

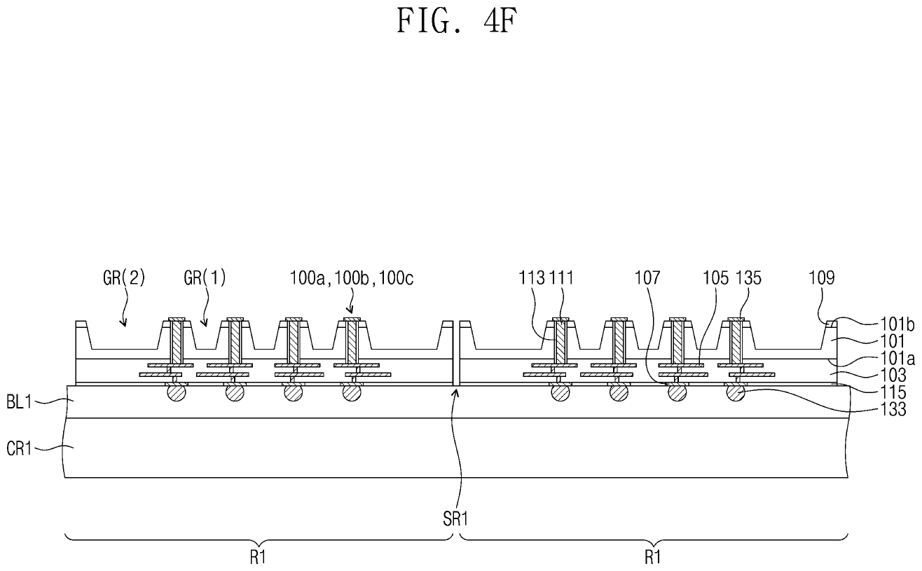

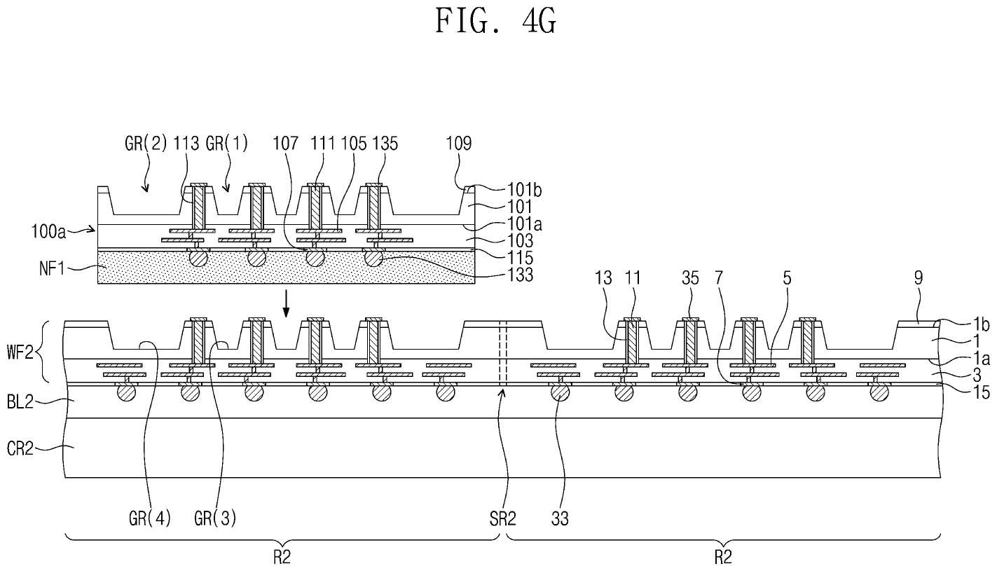

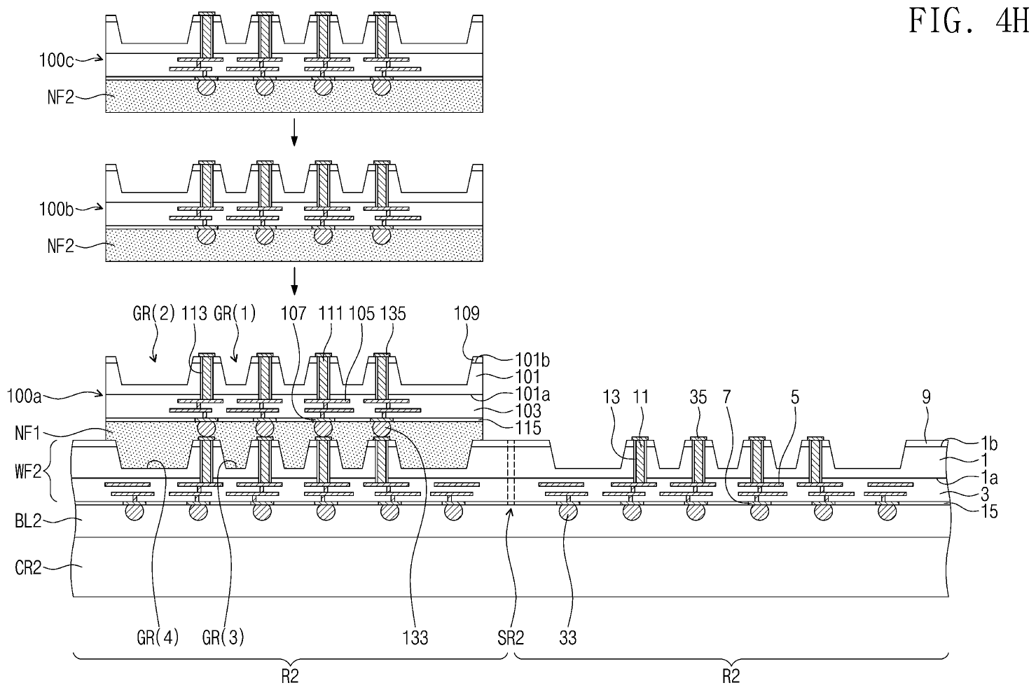

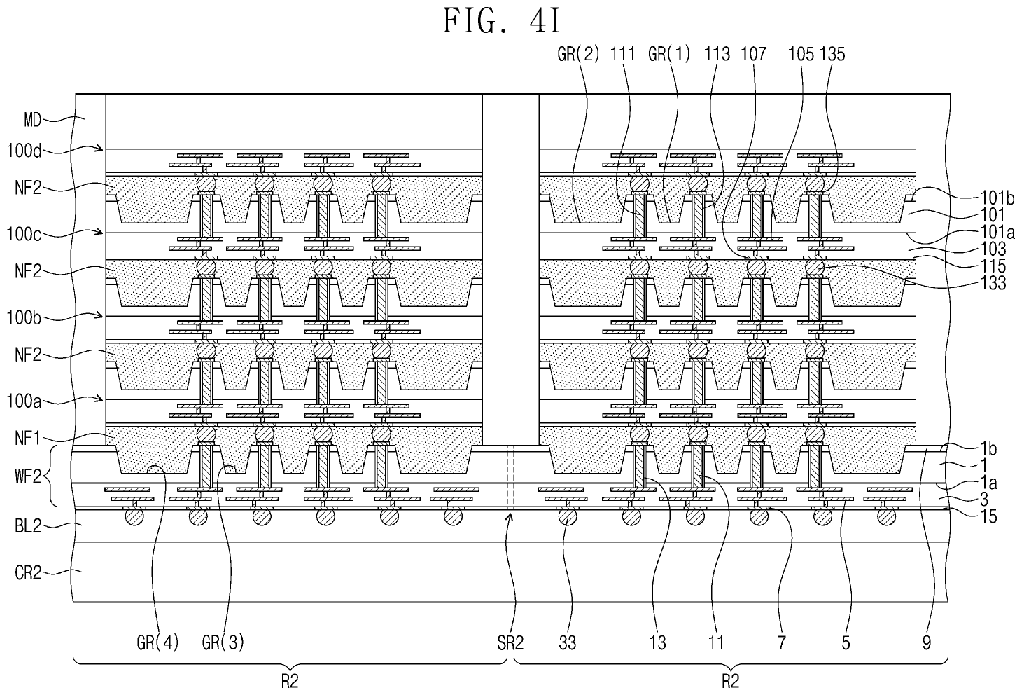

FIGS. 4A to 4H illustrate cross-sectional views showing a method of fabricating a semiconductor package having the cross-section of FIG. 1.

Referring to FIG. 4A, a first wafer structure WF1 may be prepared. The first wafer structure WF1 may have a plurality of first chip regions R1 and a first separation region SR1 therebetween. The first separation region SR1 may be a scribe lane area. The first wafer structure WF1 may include a second substrate 101. The second substrate 101 may have a second front surface 101a and a second rear surface 101b that are opposite to each other. Second transistors (not shown) may be formed on the second front surface 101a, and a portion of a second interlayer dielectric layer 103 may be formed to cover the second transistors. The portion of the second interlayer dielectric layer 103 and the second substrate 101 may be etched to form a second through hole, and a second through via 111 and a second through dielectric layer 113 may be formed in the second through hole. Second wiring lines 105 may be formed to contact the second through via 111, and a second interlayer dielectric layer 103 may be formed. Second front conductive pads 107 and a second front passivation layer 115 may be formed on the second interlayer dielectric layer 103. Second solder balls 133 may be bonded to the second front conductive pads 107. The first wafer structure WF1 may be bonded through a first adhesion layer BL1 to a first carrier substrate CR1 so as to allow the second front passivation layer 115 to face downwardly. The first adhesion layer BL1 may include an adhesive resin, a thermosetting resin, a thermoplastic resin, or a photo-curable resin.

Referring to FIG. 4B, the second rear surface 101b of the second substrate 101 may undergo a grinding or etch-back process, and thus a portion of the second substrate 101 may be removed to expose the second through dielectric layer 113. In this case, the second rear surface 101b may become lower than an end of the second through via 111. For example, the grinding process may reduce a thickness of the second substrate 101. The second through via 111 may protrude from the second rear surface 101b. A second rear passivation layer 109 may be formed on the second rear surface 101b.

Referring to FIG. 4C, a chemical mechanical polishing (CMP) process or an etch-back process may be performed to remove a portion of the second rear passivation layer 109 and a portion of the second through dielectric layer 113 to expose the second through vias 111. Second rear conductive pads 135 may be formed on the second through vias 111.

Referring to FIG. 4D or 4E, a mask pattern MK1 or MK2 may be used to etch the second rear passivation layer 109 and the second substrate 101 to form first and second grooves GR(1) and GR(2). The etching process may be an anisotropic etching process. As shown in FIG. 4D, a first mask pattern MK1 may be formed on the second rear passivation layer 109. The first mask pattern MK1 may be in contact with the second rear passivation layer 109. The first mask pattern MK1 may be a photoresist pattern. Alternatively, as shown in FIG. 4E, a second mask pattern MK2 may be positioned on the second rear passivation layer 109. The second mask pattern MK2 may be spaced apart from and may not be in contact with the second rear passivation layer 109.

Referring to FIG. 4F, a laser or a blade may be used to perform a dicing or sawing process to remove the first separation region SR1 of the first wafer structure WF1, thereby forming a plurality of semiconductor dies 100a, 100b, and 100c. Therefore, it may be possible to form second, third, and third semiconductor dies 100a, 100b, and 100c of FIG. 2. Subsequently, the semiconductor dies 100a, 100b, and 100c may be separated from the first adhesion layer BL1.

A fifth semiconductor die 100d of FIG. 2 may be formed by performing a dicing or sawing process on the first wafer structure WF1 devoid of the second through via 111, the second through dielectric layer 113, the second rear passivation layer 109, and the second rear conductive pad 135. The first wafer structure WF1 may not undergo a grinding process that reduces a thickness of the second substrate 101.

Referring to FIG. 4G, a second wafer structure WF2 may be prepared. The second wafer structure WF2 may have a plurality of second chip regions R2 and a second separation region SR2 therebetween. The second separation region SR2 may be a scribe lane area. The second wafer structure WF2 may include a first substrate 1. The second chip regions R2 may each include a structure of the first semiconductor die 10 discussed with reference to FIG. 2. First solder balls 33 may be bonded to first front conductive pads 7 positioned on a bottom surface of the second wafer structure WF2. The second wafer structure WF2 may be bonded through a second adhesion layer BL2 to a second carrier substrate CR2. The second adhesion layer BL2 may include an adhesive resin, a thermosetting resin, a thermoplastic resin, or a photo-curable resin. The second wafer structure WF2 may undergo processes identical or similar to those discussed with reference to FIGS. 4A to 4E to form a first rear passivation layer 9, a first rear conductive pad 35, and third and fourth grooves GR(3) and GR(4).

Referring to FIG. 4H, a first non-conductive layer NF1 may be coated on a bottom surface of the second semiconductor die 100a. The first non-conductive layer NF1 may be shaped like a solid flexible film. The second semiconductor die 100a may be positioned on the second chip region R2 of the second wafer structure WF2. A thermal compression process may be performed to bond the second semiconductor die 100a to the second wafer structure WF2. In this step, second solder balls 133 may be welded to the first rear conductive pads 35. In addition, the first non-conductive layer NF1 may be melted to fill a space between the first and second semiconductor dies 10 and 100a. The first non-conductive layer NF1 may be inserted into and fill the third and fourth grooves GR(3) and GR(4).

When the third and fourth grooves GR(3) and GR(4) are absent, the first non-conductive layer NF1 may outwardly protrude from lateral surfaces of the first and second semiconductor dies 10 and 100a. This may cause a reduction in reliability. However, in the present inventive concepts, the third and fourth grooves GR(3) and GR(4) may prevent the first non-conductive layer NF1 from outwardly protruding from the lateral surfaces of the first and second semiconductor dies 10 and 100a, and thus a semiconductor package may have increased reliability.

Referring to FIGS. 4H and 4I, a second non-conductive layer NF2 may be coated on each of the third to fifth semiconductor dies 100b to 100d. The third to fifth semiconductor dies 100b to 100d may be sequentially positioned on the second semiconductor die 100a, and a thermal compression process may be performed on each of the third to fifth semiconductor dies 100b to 100d. Therefore, the second solder balls 133 may be welded to the second rear conductive pads 135. The second non-conductive layer NF2 may be melted to fill a space between the second to fifth semiconductor dies 100a to 100d. The second non-conductive layer NF2 may be inserted into and fill the first and second grooves GR(1) and GR(2).

When the first and second grooves GR(1) and GR(2) are absent, the second non-conductive layer NF2 may outwardly protrude from lateral surfaces of the second to fifth semiconductor dies 100a to 100d. This may cause a reduction in reliability. However, in the present inventive concepts, the first and second grooves GR(1) and GR(2) may prevent the second non-conductive layer NF2 from outwardly protruding from the lateral surfaces of the second to fifth semiconductor dies 100a to 100d, and thus a semiconductor package may have increased reliability.

In some embodiments of the present inventive concepts, the second to fifth semiconductor dies 100a to 100d may be simultaneously stacked on the second wafer structure WF2 and concurrently bonded by a thermal compression process performed once. As the first and second non-conductive layers NF1 and NF2 are shaped like a solid film, compared to a case where a liquid layer is coated, the stacking and thermal compression process may be easily performed on the second to fifth semiconductor dies 100a to 100d.

A molding process may be performed to form a mold layer MD that covers a top surface of the second wafer structure WF2 and the lateral surfaces of the second to fifth semiconductor dies 100a to 100d.

Referring to FIGS. 2 and 41, a dicing, sawing, or singulation process using a laser or a blade may be performed such that the mold layer MD and the second wafer structure WF2 of the second separation region SR2 may be removed to fabricate a plurality of semiconductor packages 1000. Subsequently, the semiconductor packages 1000 may be separated from the second adhesion layer BL2.

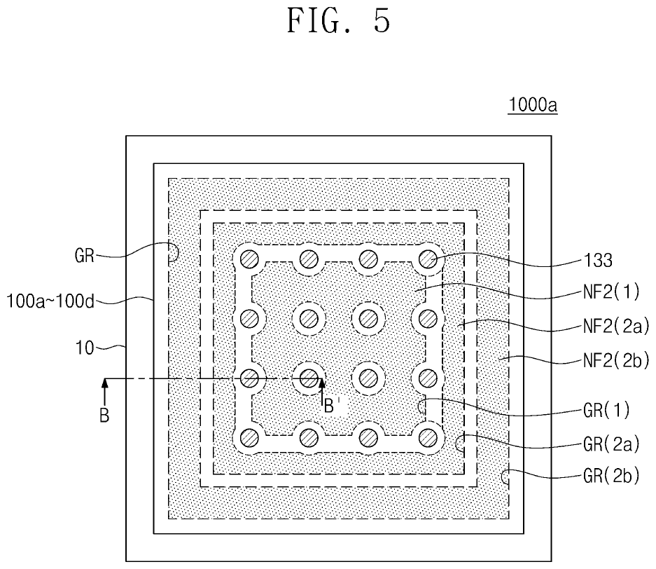

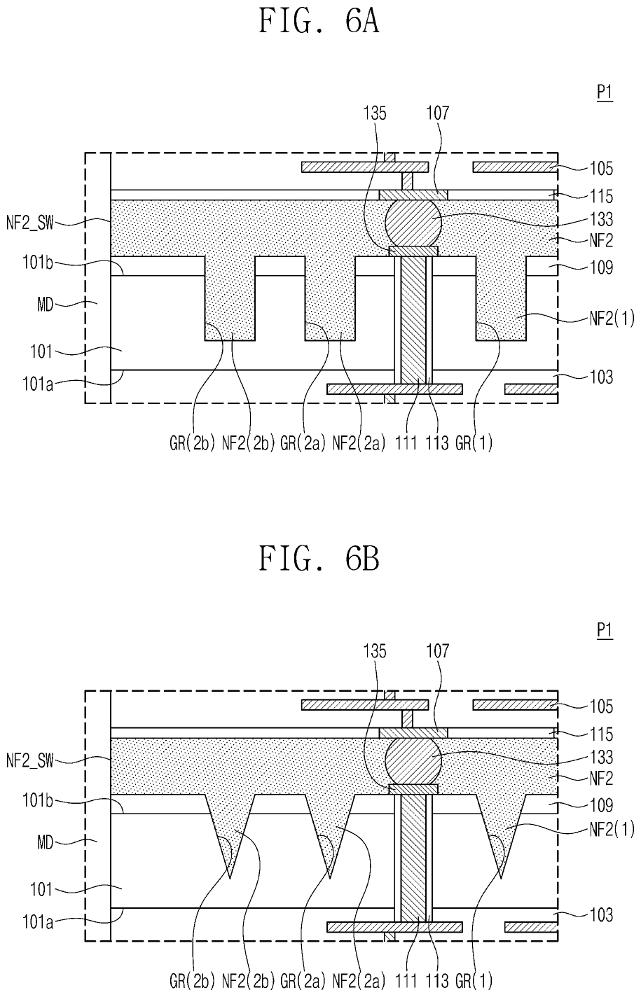

FIG. 5 illustrates a plan view showing a semiconductor package according to some embodiments of the present inventive concepts. FIGS. 6A and 6B illustrate enlarged cross-sectional views taken along line B-B′ of FIG. 5.

Referring to FIGS. 5, 6A, and 6B, in a semiconductor package 1000a according to the present embodiment, the second grooves GR(2) may be formed in the form of a plurality of (closed) line shapes. For example, the second grooves GR(2) may be divided into an a-second groove GR(2a) and a b-second groove GR(2b) and may be spaced apart from the first groove GR(1). The a-second groove GR(2a) may surround the first groove GR(1), and the b-second groove GR(2b) may surround the a-second groove GR(2a). Each of the a-second groove GR(2a) and the b-second groove GR(2b) may have a rectangular cross-section as shown in FIG. 6A or a triangular cross-section as shown in FIG. 6B. The second non-conductive layer NF2 may include an a-second dielectric part NF2(2a) and a b-second dielectric part NF2(2b). Other configurations may be identical or similar to those discussed with reference to FIGS. 1 to 3G.

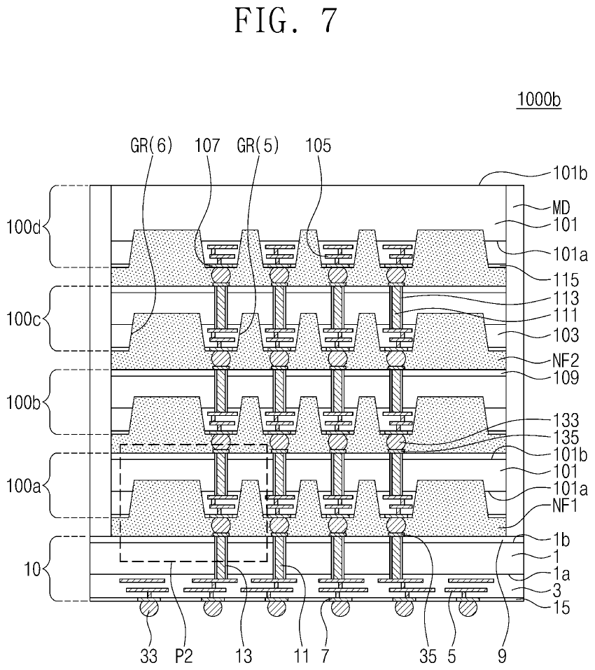

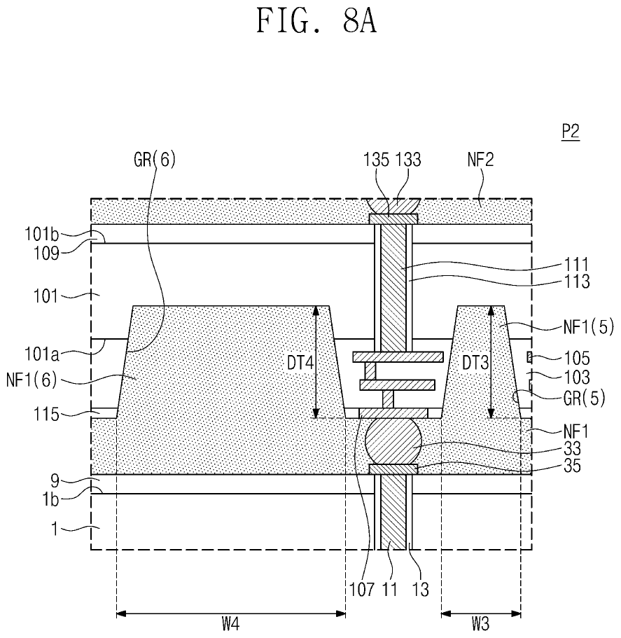

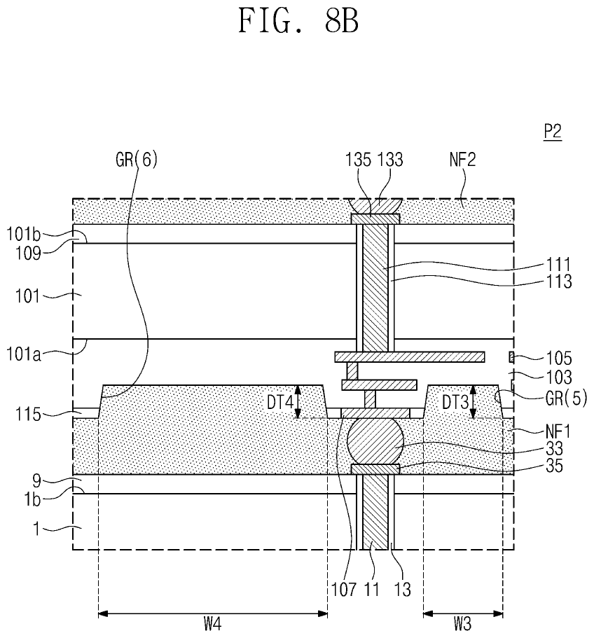

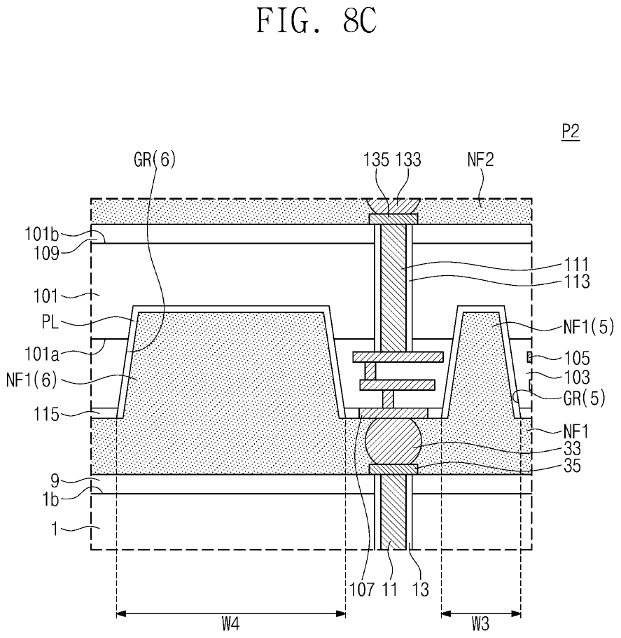

FIG. 7 illustrates a cross-sectional view showing a semiconductor package according to some embodiments of the present inventive concepts. FIGS. 8A to 8C illustrate enlarged view showing section P2 of FIG. 7.

Referring to FIGS. 7 and 8A to 8C, in a semiconductor package 1000b according to the present embodiment, the first semiconductor die 10 may have a flat top surface. The second to fifth semiconductor dies 100a to 100d may have their flat top surfaces. The second to fifth semiconductor dies 100a to 100d may have their uneven structures on bottom surfaces thereof. For example, each of the second to fifth semiconductor dies 100a to 100d may have fifth and sixth grooves GR(5) and GR(6).

As shown in FIG. 8A, the fifth and sixth grooves GR(5) and GR(6) may be formed in the second front passivation layer 115, the second interlayer dielectric layer 103, and a portion of the second substrate 101. The fifth groove GR(5) may be positioned between the second through vias 111. The fifth grooves GR(5) may have their shapes identical or similar to those of the first grooves GR(1) discussed with reference to FIGS. 3A to 3G. The sixth grooves GR(6) may be adjacent to an end of the second substrate 101. The sixth grooves GR(6) may have their shapes identical or similar to those of the second grooves GR(2) discussed with reference to FIGS. 3A to 3G. The fifth and sixth grooves GR(5) and GR(6) may be connected to or separated from each other when viewed in plan.

The first non-conductive layer NF1 may include a fifth dielectric part NF1(5) and a sixth dielectric part NF1(6). Each of the fifth grooves GR(5) may have a third width W3 and a third depth DT3. Each of the sixth grooves GR(6) may have a fourth width W4 and a fourth depth DT4. The third width W3 may be the same as or different from the fourth width W4. For example, as shown in FIG. 8A, the fourth width W4 may be greater than the third width W3. The third depth DT3 may be the same as or different from the fourth depth DT4. For example, the fourth depth DT4 may be greater than the third depth DT3. The third width W3 may range, for example, from about 1 μm to about 10 μm. The fourth depth DT4 may correspond to about 10% to about 80% of the second thickness T2.

Alternatively, as shown in FIG. 8B, the fifth and sixth grooves GR(5) and GR(6) may be formed in the second front passivation layer 115 and the second interlayer dielectric layer 103, but may not be formed in the second substrate 101. The fifth and sixth grooves GR(5) and GR(6) may vertically overlap one or a portion of the second wiring lines 105. The fifth and sixth grooves GR(5) and GR(6) may not expose the second substrate 101.

Alternatively, as shown in FIG. 8C, inner sidewalls of the fifth and sixth grooves GR(5) and GR(6) may be covered with the protection layer PL.

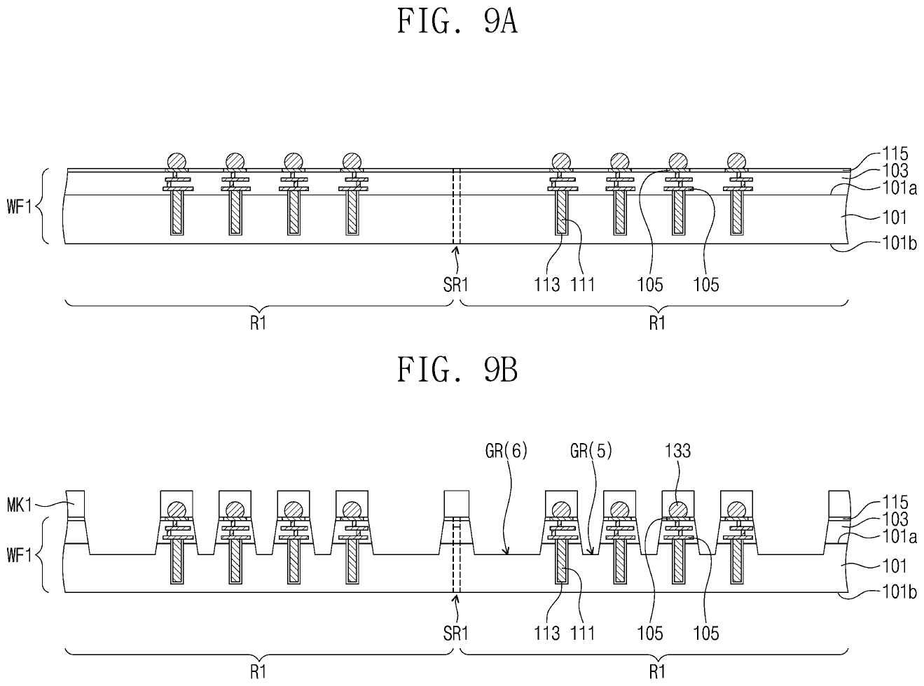

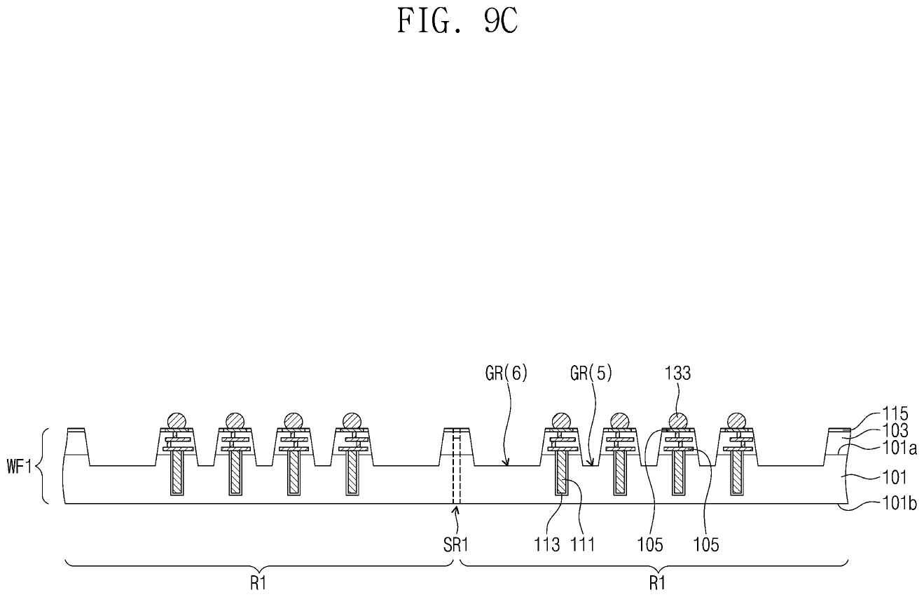

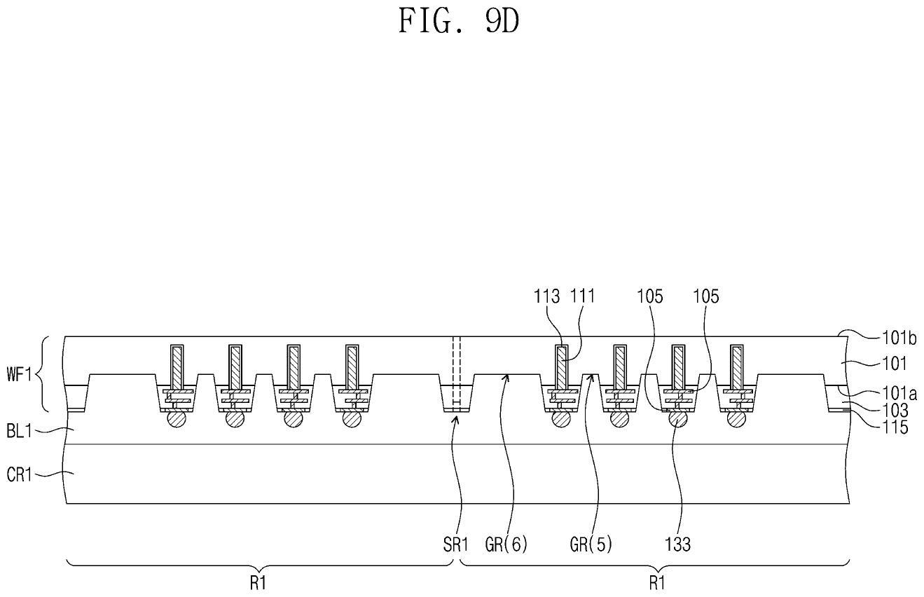

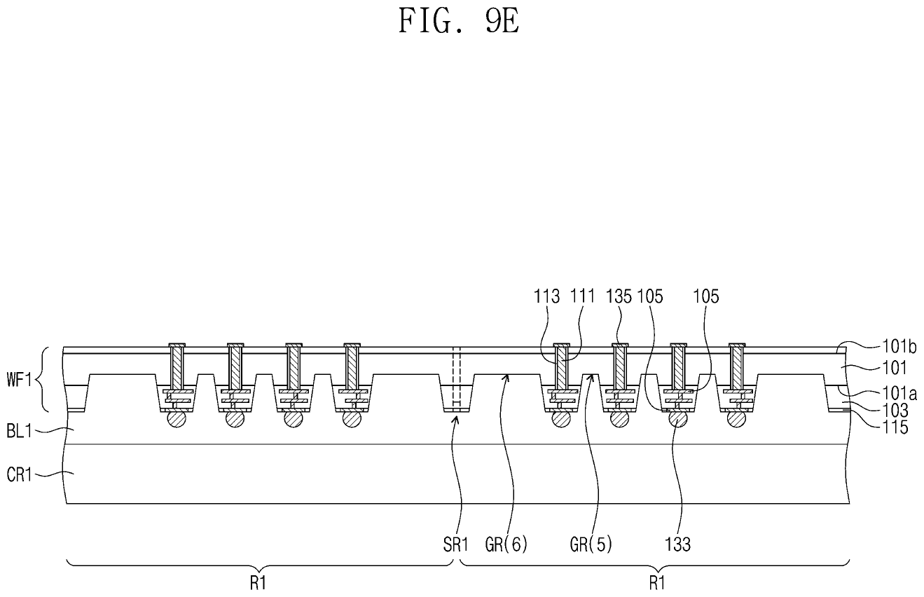

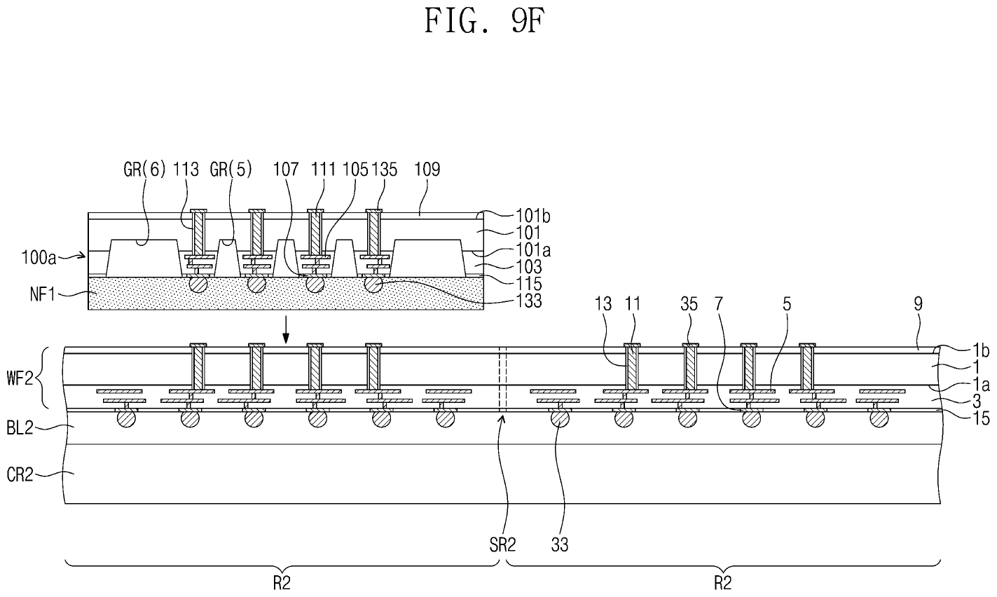

FIGS. 9A to 9F illustrate cross-sectional views showing a method of fabricating the semiconductor package of FIG. 7.

Referring to FIG. 9A, a first wafer structure WF1 may be prepared. The first wafer structure WF1 may have a plurality of first chip regions R1 and a first separation region SR1 therebetween. The first separation region SR1 may be a scribe lane area. The first wafer structure WF1 may include a second substrate 101. The second substrate 101 may have a second front surface 101a and a second rear surface 101b that are opposite to each other. Second transistors (not shown) may be formed on the second front surface 101a, and a portion of a second interlayer dielectric layer 103 may be formed to cover the second transistors. The portion of the second interlayer dielectric layer 103 and the second substrate 101 may be etched to form a second through hole, and a second through via 111 and a second through dielectric layer 113 may be formed in the second through hole. Second wiring lines 105 may be formed to contact the second through via 111, and a second interlayer dielectric layer 103 may be formed. Second front conductive pads 107 and a second front passivation layer 115 may be formed on the second interlayer dielectric layer 103. Second solder balls 133 may be bonded to the second front conductive pads 107.

Referring to FIG. 9B, a first mask pattern MK1 may be formed on the second front passivation layer 115. The first mask pattern MK1 may be a photoresist pattern. The first mask pattern MK1 may be used as an etching mask to etch the second front passivation layer 115, the second interlayer dielectric layer 103, and a portion of the second substrate 101, thereby forming fifth and sixth grooves GR(5) and GR(6). As shown in FIG. 4E, a second mask pattern MK2 may be used instead of the first mask pattern MK1.

Referring to FIGS. 9C and 9D, the first mask pattern MK1 may be removed. The first wafer structure WF1 may be bonded through a first adhesion layer BL1 to a first carrier substrate CR1 so as to allow the second front passivation layer 115 to face downwardly. The first adhesion layer BL1 may include an adhesive resin, a thermosetting resin, a thermoplastic resin, or a photo-curable resin.

Referring to FIG. 9E, the second rear surface 101b of the second substrate 101 may undergo a grinding or etch-back process, and thus a portion of the second substrate 101 may be removed to expose the second through dielectric layer 113. In this case, the second rear surface 101b may become lower than an end of the second through via 111. For example, the grinding process may reduce a thickness of the second substrate 101. The second through via 111 may protrude from the second rear surface 101b. A second rear passivation layer 109 may be formed on the second rear surface 101b. A chemical mechanical polishing (CMP) process or an etch-back process may be performed to remove a portion of the second rear passivation layer 109 and a portion of the second through dielectric layer 113 to expose the second through vias 111. Second rear conductive pads 135 may be formed on the second through vias 111.

Referring to FIGS. 9E and 9F, a laser or a blade may be used to perform a dicing or sawing process to remove the first separation region SRI of the first wafer structure WF1, thereby forming a plurality of semiconductor dies 100a, 100b, and 100c. Therefore, it may be possible to form second, third, and fourth semiconductor dies 100a, 100b, and 100c of FIG. 7. Subsequently, the semiconductor dies 100a, 100b, and 100c may be separated from the first adhesion layer BL1.

A fifth semiconductor die 100d of FIG. 7 may be formed by performing a dicing or sawing process on the first wafer structure WF1 devoid of the second through via 111, the second through dielectric layer 113, the second rear passivation layer 109, and the second rear conductive pad 135. The first wafer structure WF1 may not undergo a grinding process that reduces a thickness of the second substrate 101.

A second wafer structure WF2 may be prepared. The second wafer structure WF2 may have a plurality of second chip regions R2 and a second separation region SR2 therebetween. The second separation region SR2 may be a scribe lane area. The second wafer structure WF2 may include a first substrate 1. The second chip regions R2 may each include a structure of the first semiconductor die 10 discussed with reference to FIG. 2. First solder balls 33 may be bonded to first front conductive pads 7 positioned on a bottom surface of the second wafer structure WF2. The second wafer structure WF2 may be bonded through a second adhesion layer BL2 to a second carrier substrate CR2. The second adhesion layer BL2 may include an adhesive resin, a thermosetting resin, a thermoplastic resin, or a photo-curable resin. A first rear passivation layer 9 and a first rear conductive pad 35 may be formed on the second wafer structure WF2.

Referring to FIG. 9F, a first non-conductive layer NF1 may be coated on a bottom surface of the second semiconductor die 100a. The first non-conductive layer NF1 may be shaped like a solid flexible film. The second semiconductor die 100a may be positioned on the second chip region R2 of the second wafer structure WF2. A thermal compression process may be performed to bond the second semiconductor die 100a to the second wafer structure WF2. In this step, second solder balls 133 may be welded to the first rear conductive pads 35. In addition, the first non-conductive layer NF1 may be melted to fill a space between the first and second semiconductor dies 10 and 100a. The first non-conductive layer NF1 may be inserted into and fill the fifth and sixth grooves GR(5) and GR(6).

A second non-conductive layer NF2 may be coated on a bottom surface of each of the third to fifth semiconductor dies 100b to 100d. The third to fifth semiconductor dies 100b to 100d may be sequentially positioned on the second semiconductor die 100a, and a thermal compression process may be performed on each of the third to fifth semiconductor dies 100b to 100d. Accordingly, the semiconductor package 1000b of FIG. 7 may be fabricated.

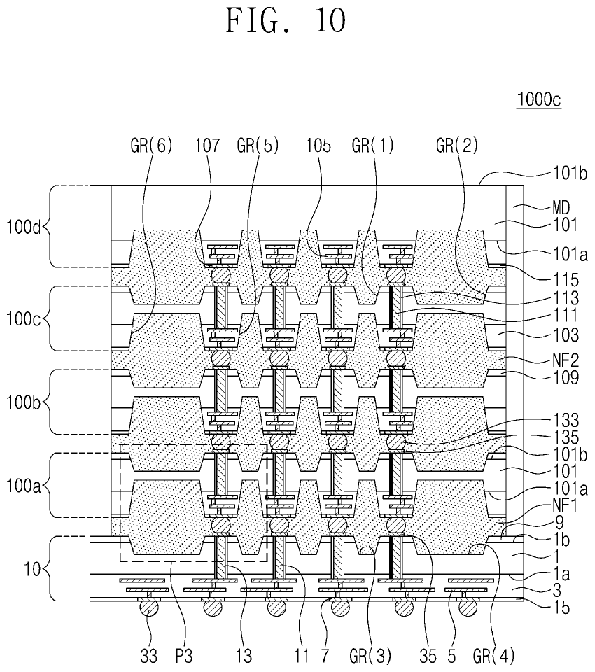

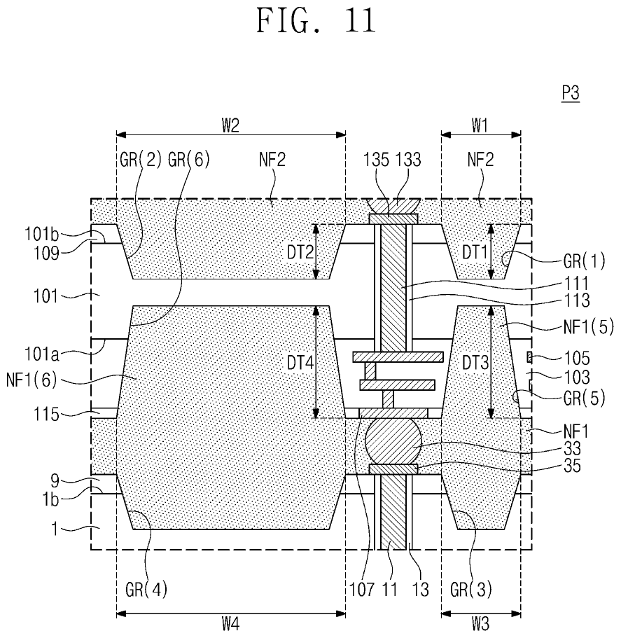

FIG. 10 illustrates a cross-sectional view showing a semiconductor package according to some embodiments of the present inventive concepts. FIG. 11 illustrates an enlarged view showing section P3 of FIG. 10.

Referring to FIGS. 10 and 11, in a semiconductor package 1000c according to the present embodiment, the first semiconductor die 10 may have an uneven structure on a top surface thereof. The second to fourth semiconductor dies 100a to 100c may have their uneven structures on top surfaces thereof. The second to fourth semiconductor dies 100a to 100c may have their uneven structures on bottom surfaces thereof. The second to fourth semiconductor dies 100a to 100c may have first, second, fifth, and sixth grooves GR(1), GR(2), GR(5), and GR(6).

The first groove GR(1) may have a first width W1 and a first depth DT1. The second groove GR(2) may have a second width W2 and a second depth DT2. The third groove GR(3) may have a third width W3 and a third depth DT3. The fourth groove GR(4) may have a fourth width W4 and a fourth depth DT4. The first width W1 may be the same as or different from the third width W3. The second width W2 may be the same as or different from the fourth width W4. The first depth DT1 may be the same as or different from the third depth DT3. The second depth DT2 may be the same as or different from the fourth depth DT4. The fifth and sixth grooves GR(5) and GR(6) may also be formed in a portion of the second substrate 101.

The firth, third, and fifth grooves GR(1), GR(3), and GR(5) may overlap each other. The second, fourth, and sixth grooves GR(2), GR(4), and GR(6) may overlap each other. The first non-conductive layer NF1 may fill the third to sixth grooves GR(3) to GR(6) between the first and second semiconductor dies 10 and 100a. The second non-conductive layer NF2 may fill the first, second, fifth, and sixth grooves GR(1), GR(2), GR(5), and GR(6) between the second to fifth semiconductor dies 100a to 100d. Other structural features may be identical or similar to those discussed above.

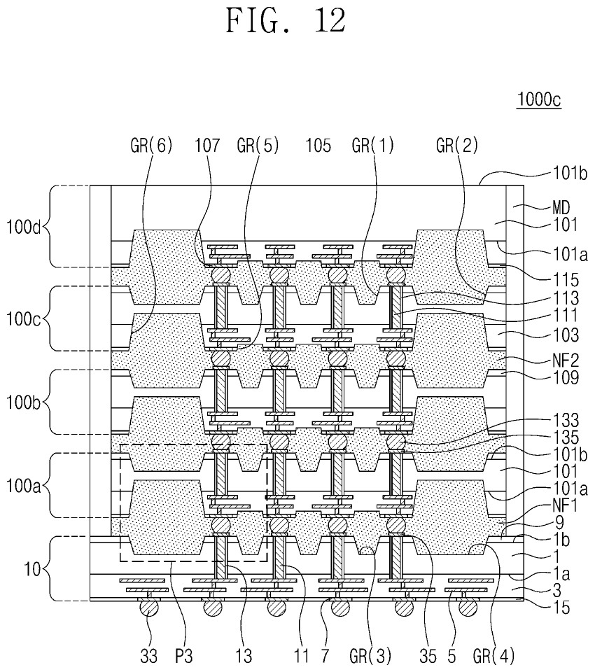

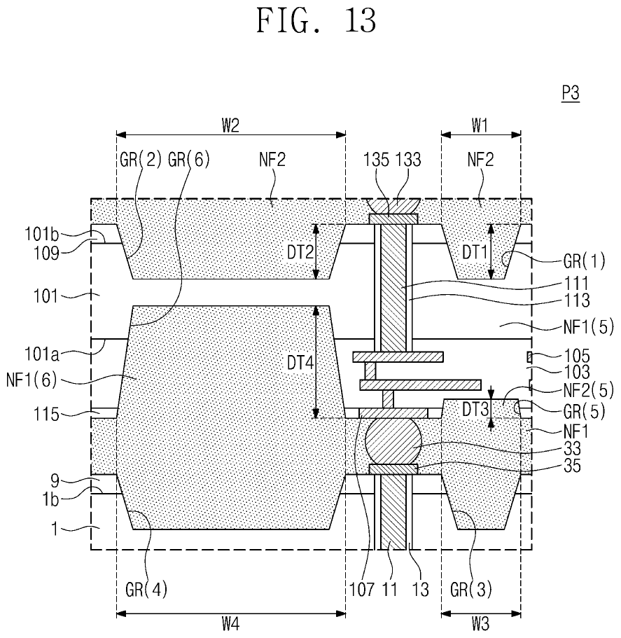

FIG. 12 illustrates a cross-sectional view showing a semiconductor package according to some embodiments of the present inventive concepts. FIG. 13 illustrates an enlarged view showing section P3 of FIG. 10.

Referring to FIGS. 12 and 13, in a semiconductor package 1000d according to the present embodiment, the fifth groove GR(5) may not be formed in the second substrate 101 and may overlap one of the second wiring lines 105. Therefore, the fifth groove GR(5) may be formed without a change in arrangement of the second wiring lines 105. The sixth groove GR(6) may also be formed in a portion of the second substrate 101. A third depth DT3 of the fifth groove GR(5) may be less than a fourth depth DT4. Other configurations may be identical or similar to those discussed above.

In the present inventive concepts, grooves formed in semiconductor dies may have various shapes to increase reliability of a semiconductor package.

In a semiconductor package according to the present inventive concepts, semiconductor dies may include grooves to prevent a non-conductive layer from outwardly protruding from lateral surfaces of the semiconductor dies or from being exposed to a lateral surface of a mold layer. As a result, the semiconductor package may have increased reliability. In addition, the grooves may have various depths, widths, and arrangements without a variation in design of wiring lines.

Although the present inventive concepts have been described in connection with some embodiments of the present inventive concepts illustrated in the accompanying drawings, it will be understood to those skilled in the art that various changes and modifications may be made without departing from the technical features of the present inventive concepts. It will be apparent to those skilled in the art that various substitution, modifications, and changes may be thereto without departing from the scope of the present inventive concepts. The embodiments of FIGS. 1 to 13 may be combined with each other.

What is claimed is:

1. A semiconductor package, comprising:
a first semiconductor die;
a plurality of second semiconductor dies stacked on the first semiconductor die, each of the second semiconductor dies having a width less than a width of the first semiconductor die;
a first non-conductive layer between the first semiconductor die and a lowermost one of the second semiconductor dies; and
a second non-conductive layer between adjacent ones of the second semiconductor dies,
wherein each of the second semiconductor dies comprises:
a first substrate that has a first front surface and a first rear surface;
a first interlayer dielectric layer that covers the first front surface;
a plurality of first through electrodes that penetrate the first substrate; and
a first passivation layer that covers the first rear surface,
wherein a first groove is in the first passivation layer and a portion of the first substrate, and
wherein the second non-conductive layer is within the first groove.

2. The semiconductor package of claim 1, wherein, on an inner sidewall of the first groove, a sidewall of the first passivation layer and a sidewall of the first substrate are aligned with each other or are offset from each other.

3. The semiconductor package of claim 1, wherein
the first groove is between the first through electrodes,
a second groove is adjacent to an edge of the first substrate and in the first passivation layer and a portion of the first substrate,
the first groove has a first width, and
the second groove has a second width greater than the first width.

4. The semiconductor package of claim 3, wherein
the first groove has a first depth, and
the second groove has a second depth greater than the first depth.

5. The semiconductor package of claim 1, wherein a cross-section of the first groove has a trapezoidal shape, a rectangular shape, a triangular shape, a curved shape, or a staircase shape.

6. The semiconductor package of claim 1, further comprising a protection layer that conformally covers an inner sidewall and a bottom surface of the first groove and is in contact with the second non-conductive layer.

7. The semiconductor package of claim 1, wherein a sidewall of the second non-conductive layer is flat or recessed toward a space between the second semiconductor dies.

8. The semiconductor package of claim 1, wherein
the first semiconductor die has a first width,
each of the second semiconductor dies has a second width less than the first width,
the first semiconductor die comprises:
a second substrate that has a second front surface and a second rear surface;
a second interlayer dielectric layer that covers the second front surface;
a plurality of second through electrodes that penetrate the second substrate; and
a second passivation layer that covers the second rear surface,
a second groove is in the second passivation layer and a portion of the second substrate, and
the first non-conductive layer is within the second groove.

9. The semiconductor package of claim 1, wherein
a second groove is in the first interlayer dielectric layer, and
one of the first non-conductive layer and the second non-conductive layer is within the second groove.

10. The semiconductor package of claim 9, wherein
the first groove has a first width and a first depth,
the second groove has a second width and a second depth,
the second width is less than the first width, and
the second depth is less than the first depth.

11. The semiconductor package of claim 10, wherein each of the second semiconductor dies further comprises a plurality of first wiring lines in the first interlayer dielectric layer,
wherein one of the first wiring lines overlaps the second groove.

12. A semiconductor package, comprising:
a first semiconductor die;
a plurality of second semiconductor dies stacked on the first semiconductor die, each of the second semiconductor dies having a width less than a width of the first semiconductor die;
a first non-conductive layer between the first semiconductor die and a lowermost one of the second semiconductor dies; and
a second non-conductive layer between adjacent ones of the second semiconductor dies,
wherein each of the second semiconductor dies comprises:
a first substrate that has a first front surface and a first rear surface;
a first interlayer dielectric layer that covers the first front surface;
a plurality of first through electrodes that penetrate the first substrate; and
a first passivation layer that covers the first rear surface,
wherein a first groove is in a portion of the first interlayer dielectric layer, and
wherein the second non-conductive layer is within the first groove.

13. The semiconductor package of claim 12, wherein the first groove extends into a portion of the first substrate.

14. The semiconductor package of claim 13, wherein, on an inner sidewall of the first groove, a sidewall of the first passivation layer and a sidewall of the first substrate are aligned with each other or are offset from each other.

15. The semiconductor package of claim 12, wherein
the first groove is between the first through electrodes,
a second groove adjacent to an edge of the first substrate and in the first interlayer dielectric layer and a portion of the first substrate,
the first groove has a first width and a first depth,
the second groove has a second width and a second depth,
the second width is greater than the first width, and
the second depth is greater than the first depth.

16. The semiconductor package of claim 12, wherein a cross-section of the first groove has a trapezoidal shape, a rectangular shape, a triangular shape, a curved shape, or a staircase shape.

17. The semiconductor package of claim 12, further comprising a protection layer that conformally covers an inner sidewall and a bottom surface of the first groove and is in contact with the second non-conductive layer.

18. The semiconductor package of claim 12, wherein
the first semiconductor die has a first width,
each of the second semiconductor dies has a second width less than the first width,
the first semiconductor die comprises:
a second substrate that has a second front surface and a second rear surface;
a second interlayer dielectric layer that covers the second front surface;
a plurality of second through electrodes that penetrate the second substrate; and
a second passivation layer that covers the second rear surface,
a second groove is in the second passivation layer and a portion of the second substrate, and
the first non-conductive layer is within the second groove.

19. A semiconductor package, comprising:
a first semiconductor die;
a plurality of second semiconductor dies stacked on the first semiconductor die, each of the second semiconductor dies having a width less than a width of the first semiconductor die;
a first non-conductive layer between the first semiconductor die and a lowermost one of the second semiconductor dies; and
a second non-conductive layer between adjacent ones of the second semiconductor dies,
wherein the first semiconductor die comprises:
a first substrate that has a first front surface and a first rear surface;
a first interlayer dielectric layer that covers the first front surface;
a plurality of first through electrodes that penetrate the first substrate; and
a first passivation layer that covers the first rear surface,
wherein a first groove is in the first passivation layer and a portion of the first substrate, and
wherein the first non-conductive layer is within the first groove,
wherein each of the second semiconductor dies comprises:
a second substrate that has a second front surface and a second rear surface;
a second interlayer dielectric layer that covers the second front surface;
a plurality of second through electrodes that penetrate the second substrate; and
a second passivation layer that covers the second rear surface,
wherein a second groove is in a portion of the second interlayer dielectric layer,
wherein a third groove is in the second passivation layer and the second substrate,
wherein the second non-conductive layer is within the second groove and the third groove, and
wherein the second groove has a first width of about 1 μm to about 10 μm.

20. The semiconductor package of claim 19, wherein
the second groove has a first depth,
the third groove has a second width and a second depth,
the second width is greater than the first width,
the second depth is greater than the first depth, and
the first depth corresponds to about 10% to about 80% of a thickness of each of the second semiconductor dies.
